(19) United States
(12) Patent Application Publication
(10) Pub. No.: US 2012/0112199 A1
(43) Pub. Date: May 10, 2012

(54) THIN FILM TRANSISTOR ARRAY PANEL

(76) Inventors: Seung Suk SON, Jung-gu (KR); Jae Hwa PARK, Gumi-si (KR)

(21) Appl. No.: 13/243,903

(22) Filed: Sep. 23, 2011

(30) Foreign Application Priority Data
Nov. 10, 2010 (KR) 10-2010-0111513

(51) Int. Cl. H01L 29/786

(52) U.S. Cl. 257/72; 257/E29.273

(57) ABSTRACT

A thin film transistor array panel according to an exemplary embodiment of the present invention floats all data lines during a manufacturing process by forming the data lines DL separate from each other and separate from the data pad connecting lines DLL, and only connecting the lines DL to the corresponding lines DLL after the data lines DL are etched. This reduces etching speed differences between data wires, thereby reducing the problem of differing thicknesses for different data lines DL. Therefore, it is possible to prevent performance deterioration or display quality deterioration of the transistor due to a thickness difference of data wires.

### CROSS-REFERENCE TO RELATED APPLICATION

This application claims priority to, and the benefit of, Korean Patent Application No. 10-2010-0111513 filed in the Korean Intellectual Property Office on Nov. 10, 2010, the entire contents of which are incorporated herein by reference.

### BACKGROUND OF THE INVENTION

(a) Field of the Invention

Embodiments of the present invention relate generally to flat panel displays.

More specifically, embodiments of the present invention relate to thin film transistor array panels.

(b) Description of the Related Art

Liquid crystal displays are currently one of the most widely used types of flat panel displays. Liquid crystal displays typically have two display panels on which electrodes are formed, and a liquid crystal layer disposed therebetween. The display controls the intensity of transmitted light by applying a voltage to the electrodes to generate electric fields that rearrange the liquid crystal molecules. The liquid crystal is rearranged to selectively allow light through the panels, thus generating an image.

One of the two display panels is a thin film transistor (TFT) display panel that is used as a circuit board for independently driving each pixel in the display. Such panels are used in both liquid crystal displays as above, and in other types of flat panel displays, such as organic electro luminescence (EL) displays, and the like.

The thin film transistor array panel typically includes a scanning signal wire or a gate wire that transmits a scanning signal, an image signal line or a data wire that transmits an image signal, a thin film transistor that is connected to the gate wire and the data wire, a pixel electrode that is connected to the thin film transistor, a gate insulating layer that covers the gate wire and insulates it, and an interlayer insulating layer that covers the thin film transistor and the data wire and insulates them.

Meanwhile, as the size of the display devices increases, the size of the thin film transistor array panel increases accordingly. As the size of the thin film transistor array panel increases, so typically does the effect of static electricity generated during the manufacturing process. To reduce the effect of this static electricity, one of the data wires at odd number positions and the data wires at even number positions are connected to each other during panel manufacture, while the others are not. However, data wires that are not connected to each other are etched at different speeds than interconnected data wires, resulting in data wires of differing thicknesses. This in turn reduces the performance of the display, resulting in deleterious effects such as vertical lines in the display, or decreased performance of some of the thin film transistors.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a thin film transistor array panel that can prevent or reduce performance deterioration or display quality deterioration of the transistor due to thickness differences in its data wires.

An exemplary embodiment of the present invention provides a thin film transistor array panel that includes a display area and a peripheral area around the display area, including: a plurality of gate lines and a plurality of data lines that are each disposed in the display area and on an insulating substrate, a plurality of data pad connecting lines that are each disposed in the peripheral area and on the insulating substrate, and a plurality of connecting members that are disposed on the substrate and that electrically connect ones of the plurality of data lines to corresponding ones of the plurality of data pad connecting lines, wherein the plurality of data pad connecting lines are formed of the same layer.

The data pad connecting line may be formed of the same layer as the gate line.

The thin film transistor array panel may further include a gate insulating layer that covers the gate line and a passivation layer that covers the data line. The passivation layer may have a first contact hole that exposes the data line, and a second contact hole may expose the data pad connecting line through the gate insulating layer and the passivation layer. Additionally, the connecting member may cover the first contact hole and the second contact hole.

The thin film transistor array panel may further include a thin film transistor connected to the gate line and the data line, and a pixel electrode electrically connected to the thin film transistor and disposed on the passivation layer, wherein the connecting member and the pixel electrode are formed of the same layer.

The data line may have a dual-layer structure that includes a lower layer and an upper layer.

The lower layer may include titanium (Ti) and the upper layer may include copper (Cu).

The data pad connecting line may be formed of the same layer as the data line.

The passivation layer may have a first contact hole that exposes the data line and a second contact hole that exposes an upper layer of the data pad connecting line, and the connecting member may cover the first contact hole and the second contact hole.

The data pad connecting line may include a lower layer that is formed of the same layer as the gate line, and an upper layer that is formed of the same layer as the data line.

The passivation layer may have a first contact hole that exposes the data line, and a second contact hole that exposes the upper layer of the data pad connecting line. A second contact hole may expose the lower layer of the data pad connecting line through the gate insulating layer and the passivation layer, and the connecting member may cover the first contact hole and the second contact hole.

Another exemplary embodiment of the present invention provides a thin film transistor array panel that includes a display area and a peripheral area around the display area. The panel includes a plurality of gate lines and a plurality of data lines that are each disposed in the display area and on an insulating substrate, as well as a plurality of data pad connecting lines disposed in the peripheral area and on the insulating substrate. The panel also has a plurality of connecting members disposed on the substrate to electrically connect the plurality of data lines and the plurality of data pad connecting lines to each other. The plurality of data pad connecting lines include a first pair of data pad connecting lines and a second pair of data pad connecting lines, where the data pad connecting lines of the first pair of data pad connecting lines are both formed of the same layer, the data pad connecting lines of the second pair of data pad connecting lines are both formed of the same layer, and the first pair of data pad connecting lines and the second pair of data pad connecting lines are formed of different layers.

The first pair of data pad connecting lines may be formed of the same layer as the gate line.

The thin film transistor array panel may further include a gate insulating layer that covers the gate line and a passivation layer that covers the data line, wherein the passivation layer has a first contact hole that exposes the data line. Also, a second contact hole exposes the first pair of data pad connecting lines through the gate insulating layer and the passivation layer, and the connecting member may cover the first contact hole and the second contact hole.

The second pair of data pad connecting lines may be formed of the same layer as the data line.

The thin film transistor array panel may further include a gate insulating layer that covers the gate line, and a passivation layer that covers the data line, wherein the passivation layer may have a first contact hole that exposes the data line, and a second contact hole that exposes the second pair of data pad connecting lines. Also, the connecting member may cover the first contact hole and the second contact hole.

According to the exemplary embodiments of the present invention, a thin film transistor array panel floats all data lines during a manufacturing process by first forming data lines DL that are electrically isolated from each other and from the data pad connecting lines DLL, then connecting the lines DL to their corresponding lines DLL after the lines DL are formed and etched. This reduces or eliminates etching speed difference between different data wires, thereby alleviating the etching speed difference between data wires. It is thus possible to prevent performance deterioration or display quality deterioration of the transistor due to thickness differences in the data wires.

### BRIEF DESCRIPTION OF THE DRAWINGS

FIG. 1 is a layout view of a thin film transistor array panel according to an exemplary embodiment of the present invention.

FIG. 2 is a cross-sectional view of a thin film transistor array panel according to an exemplary embodiment of the present invention, which is taken along line II-II of FIG. 1.

FIG. 3A is a cross-sectional view of a thin film transistor array panel according to an exemplary embodiment of the present invention, which is taken along line III-III of FIG. 1.

FIG. 3B is a cross-sectional view of a thin film transistor array panel according to another exemplary embodiment of the present invention, which is taken along line III-III of FIG. 1.

FIG. 3C is a cross-sectional view of a thin film transistor array panel according to another exemplary embodiment of the present invention, which is taken along line III-III of FIG. 1.

FIG. 4 is a layout view of a thin film transistor array panel according to another exemplary embodiment of the present invention.

FIG. 5 is a cross-sectional view of a thin film transistor array panel according to another exemplary embodiment of the present invention, which is taken along line V-V′-V″-V″′ of FIG. 4.

FIG. 6 is a cross-sectional view of a thin film transistor array panel according to another exemplary embodiment of the present invention, which is taken along the line VI-VI′-VI″-VI″′ of FIG. 4.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

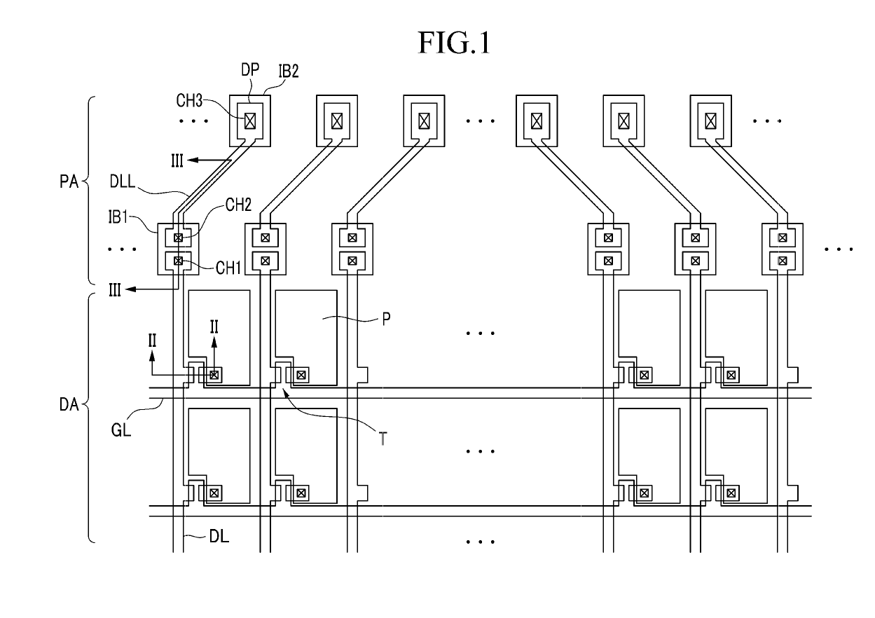

A thin film transistor array panel according to an exemplary embodiment of the present invention will be described with reference to FIG. 1. FIG. 1 is a layout view of a thin film transistor array panel according to an exemplary embodiment of the present invention.

Referring to FIG. 1, the thin film transistor array panel according to an exemplary embodiment of the present invention includes a plurality of pixels, a display area DA displaying an image, and a peripheral area PA surrounding the display area DA.

The display area DA includes a plurality of gate lines GL, a plurality of data lines DL, a plurality of transistors T, and a plurality of pixel electrodes P that are connected to the transistor T.

The peripheral area PA includes a data pad connecting line DLL and a data pad part DP. The data line DL and the data pad connecting line DLL are electrically connected to each other through the first connecting member IB1. The data line DL and the data pad connecting line DLL may be disposed on the same layer, or may be disposed on different layers. The first connecting member IB1 connects the data line DL and the data pad connecting line DLL to each other by covering both a first contact hole CH1 that exposes an end portion of the data line DL and a second contact hole CH2 that exposes the data pad connecting line DLL.

The data pad part DP is electrically connected to an external driving circuit (not shown) through a second connecting member IB2. In detail, the data pad part DP is electrically connected to the external driving circuit through both a third contact hole CH3 that exposes the data pad part DP, and the second connecting member IB2 that covers a portion of the external driving circuit.

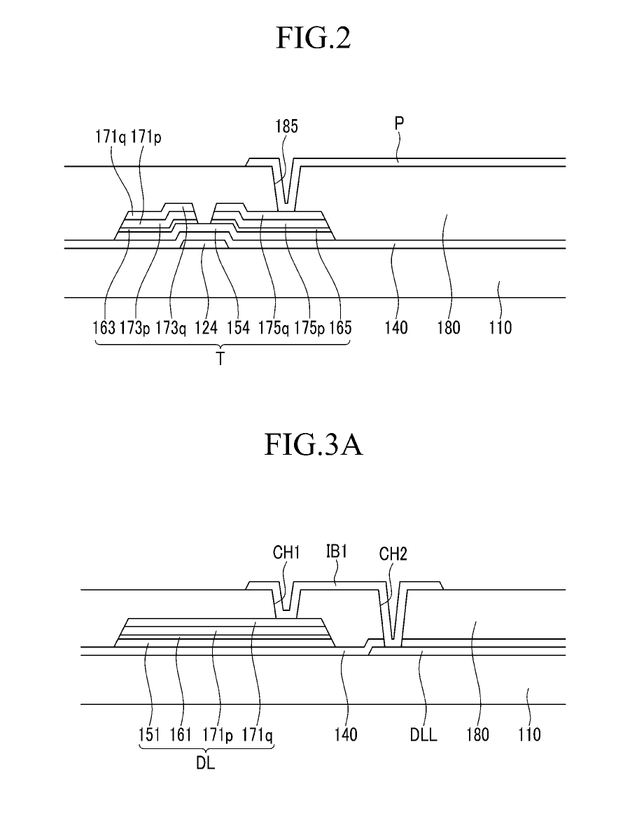

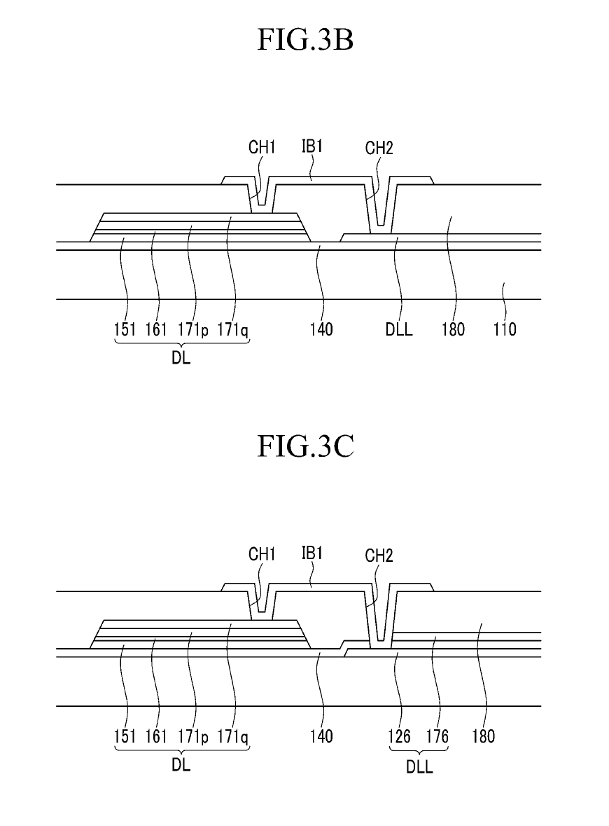

Hereinafter, a layer structure of a thin film transistor array panel according to an exemplary embodiment of the present invention will be described in detail with reference to FIGS. 2 and 3A. FIG. 2 is a cross-sectional view of a thin film transistor array panel according to an exemplary embodiment of the present invention, and which is taken along the line II-II of FIG. 1. FIG. 3A is a cross-sectional view of a thin film transistor array panel according to an exemplary embodiment of the present invention, and which is taken along the line III-III of FIG. 1.

Referring to FIG. 1 in addition to FIGS. 2 and 3A, a substrate 110 is made of a transparent material such as a glass or plastic, and a gate line GL is formed thereon. The gate line GL includes a gate electrode 124 and a data pad connecting line DLL.

The gate line 121 transfers a gate signal, and mainly extends in a horizontal direction. The gate line 121 includes a plurality of gate electrodes 124 that protrudes from the gate line 121, and an end portion having a wide area (not shown) for connection with another layer or external driving circuit.

A gate insulating layer 140 that is made of silicon nitride (SiNx) or silicon oxide (SiOx) is formed on the gate line 121 and data pad connecting line DLL. A semiconductor 154, ohmic contacts 163 and 165, a data line DL including a source electrode 173, and a drain electrode 175 are formed on the gate insulating layer 140.

The data line DL transfers a data signal, and mainly extends in a vertical direction to cross the gate line GL. The data line DL includes source electrode 173, which extends toward the gate electrode 124. The drain electrode 175 is separated from the data line DL, and faces the source electrode 173 over the gate electrode 124.

One gate electrode 124, one source electrode 173 and one drain electrode 175 together form one thin film transistor (TFT) in conjunction with the semiconductor 151, and a channel of the thin film transistor is formed at the semiconductor 154 between the source electrode 173 and drain electrode 175.

The data line DL and drain electrode 175 each have a dual-layer structure that includes lower layers 171p, 173p, and 175p and upper layers 171q, 173q, and 175q. The lower layers 171p, 173p, and 175p may include titanium (Ti), and the upper layers 171q, 173q, and 175q may include copper (Cu).

The semiconductor 154 has substantially the same plane shape as the data line DL, drain electrode 175 and ohmic contacts 163 and 165 therebeneath. However, the semiconductor 154 has exposed portions that are not covered by the source electrode 173, drain electrode 175, or data line DL.

A semiconductor stripe layer 151 and a ohmic contact stripe 161 are disposed under the data line DL. The semiconductor stripe layer 151 and ohmic contact stripe 161 may have the same plane shape as the data line DL.

Next, a passivation layer 180 is formed on the data line DL, drain electrode 175 and exposed portion of the semiconductor 154.

The passivation layer 180 can be made of either an inorganic insulator or an organic insulator, and may have a flat surface. As examples of the inorganic insulator, the passivation layer 180 can be made of silicon nitride and/or silicon oxide. The organic insulator may have photosensitivity, and for at least some applications, it may be desirable for the dielectric constant thereof to be about 4.0 or less. The passivation layer 180 may also have a dual-layer structure with a lower inorganic layer and an upper organic layer. The passivation layer 180 may also have a dual-layer structure with a lower inorganic layer and an upper inorganic layer such as SiOx and SiNx.

A first contact hole CH1 is formed in the passivation layer 180 to expose an end portion of the data line DL, and a second contact hole CH2 and a third contact hole CH3 are formed in the passivation layer 180 and gate insulating layer 140 to expose the data pad connecting line DLL and the data pad part DP, respectively.

A pixel electrode P, a first connecting member IB1, and a second connecting member IB2 are then formed on the passivation layer 180. They may be made of a transparent conductive material such as ITO or IZO, or a reflective metal such as aluminum, silver, chromium or an alloy thereof.

The end portion of the data line DL that is exposed through the first contact hole CH1 and the data pad connecting line DLL that is exposed through the second contact hole CH2 are electrically connected to each other via the first connecting member IB1. Similarly, the data pad part DP that is exposed through the third contact hole CH3 is connected with a data driving circuit (not shown) via second connecting member IB2. The data driving circuit (not shown) that generates the data signal can be disposed on a flexible printed circuit film (not shown) that is attached to the substrate 110, directly disposed on the substrate 110, or integrated on the substrate 110.

The thin film transistor array panel of this exemplary embodiment floats all data lines during manufacturing, so that the data lines are not connected to each other during manufacturing of the data lines and a semiconductor layer. After the data lines DL are all manufactured, i.e. after they are etched, the data lines DL are connected to their corresponding data pad connecting lines DLL. By forming the data lines DL separate from (and electrically isolated from) each other, and only connecting them to their data pads DP and connecting lines DLL after the data lines DL are formed and etched, the data lines DL are thus each etched at substantially the same speed Each thus has substantially the same thickness. This prevents or reduces any performance deterioration or display quality deterioration of the transistor due to thickness differences between the data wires due to different etching speeds.

A layer structure of a thin film transistor array panel according to another exemplary embodiment of the present invention will now be described with reference to FIG. 1, in conjunction with FIGS. 2 and 3B. FIG. 3B is a cross-sectional view of a thin film transistor array panel according to another exemplary embodiment of the present invention, which is taken along the line III-III of FIG. 1.

The layer structure of the thin film transistor array panel according to the exemplary embodiment shown in FIG. 3B is similar to that of FIG. 3A.

In the case of a display area, a gate line GL, including a gate electrode 124, is formed on a substrate 110. Next, a gate insulating layer 140 is formed on the gate line GL, and a semiconductor 154, ohmic contacts 163 and 165, a data line DL including a source electrode 173, a drain electrode 175, and a data pad connecting line DLL are each formed on the gate insulating layer 140.

A passivation layer 180 is then formed on the data line DL, drain electrode 175, exposed semiconductor 154, and data pad connecting line DLL.

A first contact hole CH1, a second contact hole CH2, and a third contact hole CH3 are formed in the passivation layer 180 to expose an end portion of data line DL, an end portion of the data pad connecting line DLL, and data pad part DP, respectively.

A pixel electrode P, a first connecting member IB1, and a second connecting member IB2 are formed on the passivation layer 180.

The end portion of the data line DL that is exposed through the first contact hole CH1 and the data pad connecting line DLL that is exposed through the second contact hole CH2 are electrically connected to each other via the first connecting member IB1. Similarly, the data pad part DP that is exposed through the third contact hole CH3 is connected to a data driving circuit (not shown) via the second connecting member IB2.

However, unlike the thin film transistor array panel of FIG. 3A, the data pad connecting line DLL is formed of the same layer as the data line DL. In the present embodiment, the data pad connecting line DLL has a single-layer structure, but like the data line DL, it may alternatively have a dual-layer structure that includes a lower layer and an upper layer. The semiconductor layer and ohmic contact layer may have the same plane shape, and be disposed therebeneath.

The thin film transistor array panel according to the exemplary embodiment floats all data lines during manufacturing, so that the data lines are not connected to each other during manufacturing. After the data lines DL are all manufactured, i.e. after they are etched, the data lines DL are connected to their corresponding data pad connecting lines DLL. By forming the data lines DL separate from (and electrically isolated from) each other, and only connecting them to their data pads DP and connecting lines DLL after the data lines DL are formed and etched, the data lines DL are thus each etched at substantially the same speed. Each thus has substantially the same thickness. This embodiment thus provides the same advantages as the previous embodiment.

A layer structure of a thin film transistor array panel according to another embodiment of the present invention will now be described in detail with reference to FIG. 1 in conjunction with FIGS. 2 and 3C. FIG. 3C is a cross-sectional view of a thin film transistor array panel according to another exemplary embodiment of the present invention, which is taken along the line III-III of FIG. 1.

The layer structure of the thin film transistor array panel according to the exemplary embodiment shown in FIG. 3C is similar to that of FIG. 3A or FIG. 3B.

In the display area, a gate line GL, including a gate electrode 124 and a lower layer 126 of a data pad connecting line DLL, are formed on an substrate 110. Next, a gate insulating layer 140 is formed on the gate line GL, and a semiconductor 154, ohmic contacts 163 and 165, a data line DL including a source electrode 173, a drain electrode 175, and an upper layer 176 of the data pad connecting line DLL are each formed on the gate insulating layer 140.

A passivation layer 180 is then formed on the data line DL, drain electrode 175, exposed semiconductor 154 and upper layer 176 of the data pad connecting line DLL.

A first contact hole CH1 and a third contact hole CH3 are formed in the passivation layer 180 to expose an end portion of data line DL and the data pad part DP respectively. A second contact hole CH2 is formed in the passivation layer 180 and gate insulating layer 140 to expose an end portion of the upper layer 176 of the data pad connecting line DLL and the lower layer 126 of the data pad connecting line DLL.

A pixel electrode P, a first connecting member IB1, and a second connecting member IB2 are next formed on the passivation layer 180.

An end portion of the data line DL that is exposed through the first contact hole CH1 and the data pad connecting line DLL that is exposed through the second contact hole CH2 are electrically connected to each other via first connecting member IB1. Similarly, the data pad part DP that is exposed through the third contact hole CH3 is connected with a data driving circuit (not shown) via second connecting member IB2.

However, unlike the thin film transistor array panel of FIG. 3A, the data pad connecting line DLL includes a lower layer 126 that is formed of the same layer as the gate line GL, and an upper layer 176 that is formed of the same layer as the data line DL. In this exemplary embodiment, the upper layer 176 of the data pad connecting line DLL is formed as a single-layered structure, but like the data line DL, it may also have a dual-layer structure that includes a lower layer and an upper layer. Additionally, the semiconductor layer and ohmic contact layer may have the same plane shape and be disposed therebeneath.

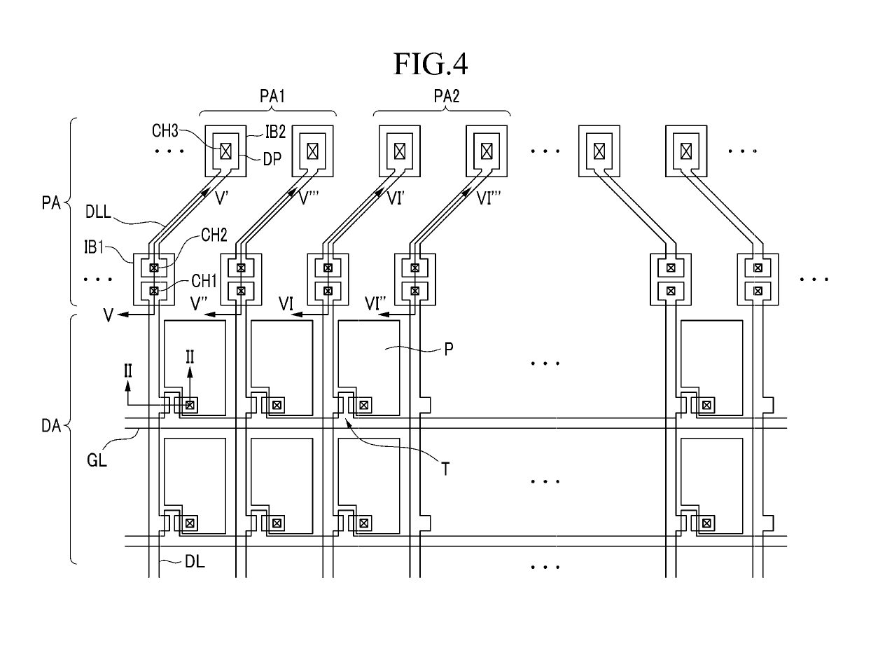

A thin film transistor array panel according to another exemplary embodiment of the present invention will now be described with reference to FIG. 4. FIG. 4 is a layout view of a thin film transistor array panel according to another exemplary embodiment of the present invention.

Referring to FIG. 4, the thin film transistor array panel according to the present exemplary embodiment is similar to the thin film transistor array panel of FIG. 1. Referring to FIG. 4, the thin film transistor array panel according to the present exemplary embodiment includes a plurality of pixels, a display area DA displaying an image, and a peripheral area PA disposed around the display area DA.

The display area DA includes a plurality of gate lines GL, a plurality of data lines DL, a plurality of transistors T, and a plurality of pixel electrodes P that are connected to the transistor T.

The peripheral area PA includes a data pad connecting line DLL and a data pad part DP. The data line DL that is disposed in the display area DA and the data pad connecting line DLL that is disposed in the peripheral area PA are electrically connected to each other through a first connecting member IB1. The data line DL and the data pad connecting line DLL may be disposed on the same layer, or may be disposed on different layers. The first connecting member IB1 connects the data line DL and the data pad connecting line DLL to each other by covering both a first contact hole CH1 that exposes an end portion of the data line DL, and a second contact hole CH2 that exposes the data pad connecting line DLL.

The data pad part DP is electrically connected to an external driving circuit (not shown) through the second connecting member IB2. In detail, the data pad part DP is electrically connected to the external driving circuit through the third contact hole CH3 and the second connecting member IB2 that covers a portion of the external driving circuit.

However, the thin film transistor array panel of this exemplary embodiment, unlike the thin film transistor array panel of FIG. 1, data pad connecting lines DLL are grouped into pairs PA1 and PA2, with the lines DLL of alternating pairs being formed of different layers. For example, odd pairs of lines DLL are formed of one layer, while even lines DLL are formed of another layer. In detail, a pair of data pad connecting lines DLL that are connected to a first pair of pixel columns PA1 and other pair of data pad connecting lines DLL that are connected to a second pair of pixel columns PA2 may be alternately disposed and may be formed of different layers

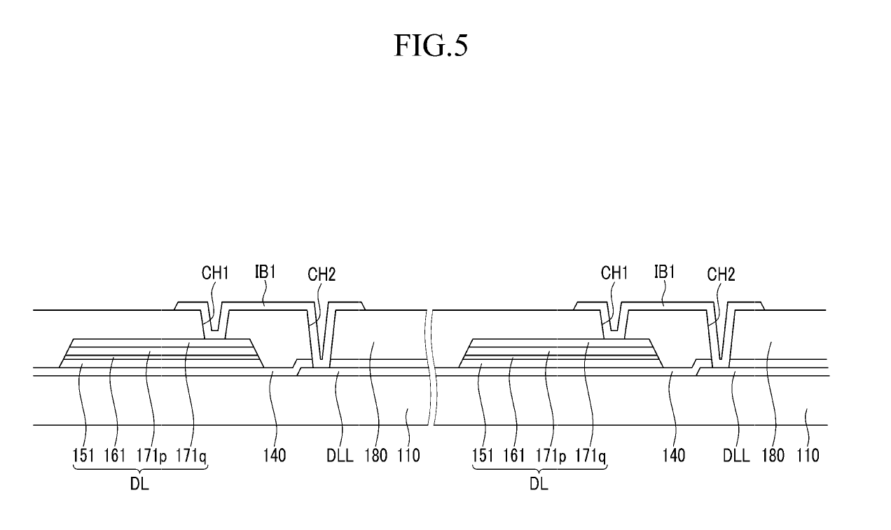

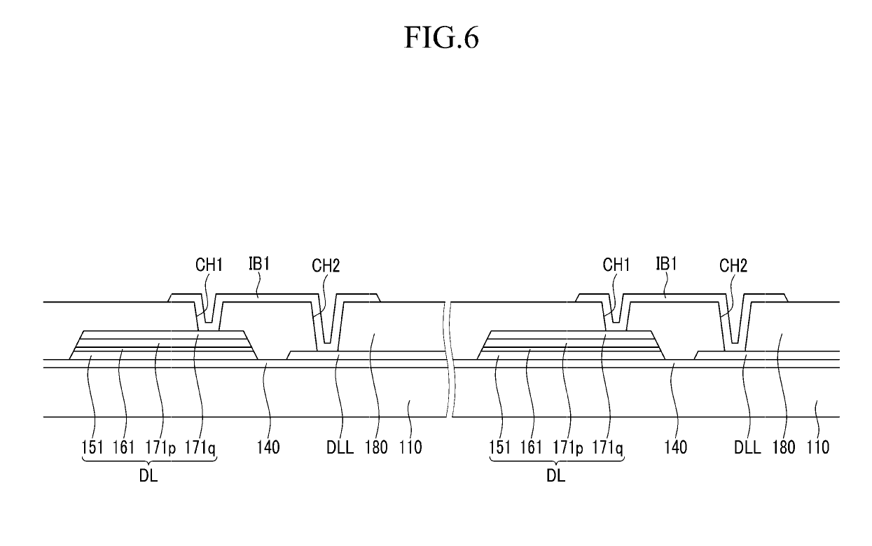

Next, a layer structure of a thin film transistor array panel according to a further exemplary embodiment of the present invention will be described with reference to FIGS. 5 and 6 in conjunction with FIGS. 2 and 4. The layer structure of the thin film transistor array panel of this exemplary embodiment is similar to that of the thin film transistor array panel as described above.

In the display area, a gate line GL, including a gate electrode 124 and a first pair of data pad part connecting lines DLL, are formed on a substrate 110. Next, a gate insulating layer 140 is formed on the gate line GL, and a semiconductor 154, ohmic contacts 163 and 165, a data line DL including a source electrode 173, a drain electrode 175, and a second pair of data pad connecting lines DLL are formed on the gate insulating layer 140.

A passivation layer 180 is then formed on the data line DL, drain electrode 175, exposed semiconductor 154, and second pair of data pad connecting lines DLL.

A first contact hole CH1, a second contact hole CH2, and a third contact hole CH3 are formed in the passivation layer 180 and gate insulating layer 140 to expose an end portion of the data line DL, an end portion of the data pad connecting line DLL, and data pad part DP, respectively.

A pixel electrode P, a first connecting member IB1, and a second connecting member IB2 are formed on the passivation layer 180.

An end portion of the data line DL that is exposed through the first contact hole CH1 and the data pad connecting line DLL that is exposed through the second contact hole CH2 are electrically connected to each other via the first connecting member IB1. Similarly, a data pad part DP that is exposed through the third contact hole CH3 is connected to a data driving circuit (not shown) via the second connecting member IB2.

However, unlike the previous embodiment, the thin film transistor array panel of the present exemplary embodiment has a first pair of data pad connecting lines DLL formed of the same layer as the gate line GL, and a second pair of data pad connecting lines DLL formed of the same layer as the data line DL. In this embodiment, the second pair of data pad connecting lines DLL are formed of a single-layered structure, but like the data line DL, they may also have a dual-layer structure that includes a lower layer and an upper layer. The semiconductor layer and ohmic contact layer may have the same plane shape and be disposed therebeneath.

The thin film transistor array panel of this embodiment floats all data lines during a manufacturing process, so as to reduce or eliminate differences in etching speed between data lines. As above, the data lines are formed separate from each other, and separate from their respective data pads, so that each data line is, initially, electrically isolated from the other data lines. Only after the data lines are etched to their proper shapes, are they connected to their respective data pads. In this manner, etching speed difference between data wires is largely prevented, thus providing for data lines that have more uniform thicknesses and shapes. Therefore, it is possible to prevent or reduce performance deterioration or display quality deterioration of the transistor due to thickness differences between the different lower layers of the data wires.

In addition, alternating pairs of data pad connecting lines DLL are formed of different layers. For example, a first pair of data pad connecting lines DLL are formed of the same layer as the gate line GL, and a second pair of data pad connecting lines DLL are formed of the same layer as the data line DL. If the first and second pairs are disposed in alternating manner, for example when four pixel electrodes form one pixel, two data pad connecting lines DLL that are connected to two pixel electrodes and two data pad connecting lines DLL that are connected to the remaining two pixel electrodes may be disposed on different layers. In this manner, even though many pixel electrodes are disposed in a narrow region, a region margin where the data pad connecting line DLL can be disposed may be ensured.

The thin film transistor array panel according to the exemplary embodiment floats all data lines during a manufacturing process by connecting them with each other through a contact hole and a connecting member, such that an etching speed difference between data wires does not occur, thereby removing the etching speed difference between data wires. Therefore, it is possible to prevent performance deterioration or display quality deterioration of the transistor due to thickness differences between different data wires.

Although not shown in the drawings, the thin film transistor array panel according to another exemplary embodiment of the present invention, unlike the thin film transistor array panel according to the exemplary embodiment shown in FIG. 1 or the thin film transistor array panel according to the exemplary embodiment shown in FIG. 4, may include data pad connecting lines DLL that are connected to each pixel column and alternately disposed. In more detail, first and second pairs of data pad connecting lines DLL may be disposed in alternating manner, and for example, the first pair may be formed of the same layer as the gate line, and the second pair may be formed of the same layer as the data line. The individual lines of each pair are formed of the same layer.

Like the thin film transistor array panel according to the exemplary embodiment, even though many pixel electrodes are disposed in a narrow region, a region margin that can form the data pad connecting line DLL may be ensured by alternately forming the data pad connecting lines DLL on the different layers.

The thin film transistor array panel according to the exemplary embodiment, like the thin film transistor array panel according to the exemplary embodiment as described above, may float all data lines during a manufacturing process by connecting them with each other through a contact hole and a connecting member only after the data lines DL are etched. In this manner, the data wires are all etched at the same rate. This ensures more even thickness of the data wires, preventing performance and/or display quality degradation due to different-thickness data wires.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel that includes a display area and a peripheral area around the display area, comprising:
a plurality of gate lines and a plurality of data lines that are each disposed in the display area and on an insulating substrate;
a plurality of data pad connecting lines that are each disposed in the peripheral area and on the insulating substrate; and
a plurality of connecting members that are disposed on the substrate and that electrically connect ones of the plurality of data lines to corresponding ones of the plurality of data pad connecting lines,
wherein the plurality of data pad connecting lines are formed of the same layer.

2. The thin film transistor array panel of claim 1, wherein:
the data pad connecting line is formed of the same layer as the gate line.

3. The thin film transistor array panel of claim 2, further comprising:
a gate insulating layer that covers the gate line, and
a passivation layer that covers the data line,
wherein the passivation layer has a first contact hole that exposes the data line,
wherein a second contact hole exposes the data pad connecting line through the gate insulating layer and the passivation layer, and
wherein the connecting member covers the first contact hole and the second contact hole.

4. The thin film transistor array panel of claim 3, further comprising:
a thin film transistor connected to the gate line and the data line, and
a pixel electrode electrically connected to the thin film transistor and disposed on the passivation layer,
wherein the connecting member and the pixel electrode are formed of the same layer.

5. The thin film transistor array panel of claim 4, wherein:
the data line has a dual-layer structure that includes a lower layer and an upper layer.

6. The thin film transistor array panel of claim 5, wherein:
the lower layer includes titanium (Ti), and the upper layer includes copper (Cu).

7. The thin film transistor array panel of claim 2, wherein:
the data line has a dual-layer structure that includes a lower layer and an upper layer.

8. The thin film transistor array panel of claim 7, wherein:
the lower layer includes titanium (Ti), and the upper layer includes copper (Cu).

9. The thin film transistor array panel of claim 1, wherein:
the data pad connecting line is formed of the same layer as the gate line.

10. The thin film transistor array panel of claim 9, further comprising:
a gate insulating layer that covers the gate line, and
a passivation layer that covers the data line,
wherein the passivation layer has a first contact hole that exposes the data line, and a second contact hole that exposes the data pad connecting line, and
wherein the connecting member covers the first contact hole and the second contact hole.

11. The thin film transistor array panel of claim 10, further comprising:
a thin film transistor connected to the gate line and the data line, and
a pixel electrode electrically connected to the thin film transistor and disposed on the passivation layer,
wherein the connecting member and the pixel electrode are formed of the same layer.

12. The thin film transistor array panel of claim 11, wherein:
the data line has a dual-layer structure that includes a lower layer and an upper layer.

13. The thin film transistor array panel of claim 12, wherein:
the lower layer includes titanium (Ti), and the upper layer includes copper (Cu).

14. The thin film transistor array panel of claim 9, wherein:
the data line has a dual-layer structure that includes a lower layer and an upper layer.

15. The thin film transistor array panel of claim 14, wherein:
the lower layer includes titanium (Ti), and the upper layer includes copper (Cu).

16. The thin film transistor array panel of claim 1, wherein:
the data pad connecting line includes a lower layer that is formed of the same layer as the gate line, and an upper layer that is formed of the same layer as the data line.

17. The thin film transistor array panel of claim 16, further comprising:
a gate insulating layer that covers the gate line, and
a passivation layer that covers the data line,
wherein the passivation layer has a first contact hole that exposes the data line, and a second contact hole that exposes the upper layer of the data pad connecting line,
wherein a second contact hole exposes the lower layer of the data pad connecting line through the gate insulating layer and the passivation layer, and
wherein the connecting member covers the first contact hole and the second contact hole.

18. The thin film transistor array panel of claim 17, further comprising:
a thin film transistor that is connected to the gate line and the data line, and
a pixel electrode electrically connected to the thin film transistor and disposed on the passivation layer,
wherein the connecting member and the pixel electrode are formed of the same layer.

19. The thin film transistor array panel of claim 18, wherein:
the data line has a dual-layer structure that includes a lower layer and an upper layer.

20. The thin film transistor array panel of claim 19, wherein:
the lower layer includes titanium (Ti), and the upper layer includes copper (Cu).

21. The thin film transistor array panel of claim 16, wherein:
the data line has a dual-layer structure that includes a lower layer and an upper layer.

22. The thin film transistor array panel of claim 21, wherein:
the lower layer includes titanium (Ti) and the upper layer includes copper (Cu).

23. A thin film transistor array panel that includes a display area and a peripheral area around the display area, comprising,
a plurality of gate lines and a plurality of data lines each disposed in the display area and on an insulating substrate;
a plurality of data pad connecting lines disposed in the peripheral area and on the insulating substrate; and
a plurality of connecting members disposed on the substrate to electrically connect the plurality of data lines and the plurality of data pad connecting lines to each other,
wherein the plurality of data pad connecting lines include a first pair of data pad connecting lines and a second pair of data pad connecting lines, the data pad connecting lines of the first pair of data pad connecting lines are both formed of the same layer, the data pad connecting lines of the second pair of data pad connecting lines are both formed of the same layer, and the first pair of data pad connecting lines and the second pair of data pad connecting lines are formed of different layers.

24. The thin film transistor array panel of claim 23, wherein:
the first pair of data pad connecting lines are formed of the same layer as the gate line.

25. The thin film transistor array panel of claim 24, further comprising:
a gate insulating layer that covers the gate line, and
a passivation layer that covers the data line,
wherein the passivation layer has a first contact hole that exposes the data line,
wherein a second contact hole exposes the first pair of data pad connecting lines through the gate insulating layer and the passivation layer, and
wherein the connecting member covers the first contact hole and the second contact hole.

26. The thin film transistor array panel of claim 25, further comprising:
a thin film transistor connected to the gate line and the data line, and
a pixel electrode electrically connected to the thin film transistor and disposed on the passivation layer,
wherein the connecting member and the pixel electrode are formed of the same layer.

27. The thin film transistor array panel of claim 26, wherein:
the data line has a dual-layer structure that includes a lower layer and an upper layer.

28. The thin film transistor array panel of claim 27, wherein:
the lower layer includes titanium (Ti) and the upper layer includes copper (Cu).

29. The thin film transistor array panel of claim 24, wherein:
the second pair of data pad connecting lines are formed of the same layer as the data line.

30. The thin film transistor array panel of claim 23, wherein:
the second pair of data pad connecting lines are formed of the same layer as the data line.

31. The thin film transistor array panel of claim 30, further comprising:
a gate insulating layer that covers the gate line, and
a passivation layer that covers the data line,
wherein the passivation layer has a first contact hole that exposes the data line, and a second contact hole that exposes the second pair of data pad connecting lines, and
wherein the connecting member covers the first contact hole and the second contact hole.

32. The thin film transistor array panel of claim 31, further comprising:
a thin film transistor connected to the gate line and the data line, and
a pixel electrode electrically connected to the thin film transistor and disposed on the passivation layer,
wherein the connecting member and the pixel electrode are formed of the same layer.

33. The thin film transistor array panel of claim 32, wherein:
the data line has a dual-layer structure that includes a lower layer and an upper layer.

34. The thin film transistor array panel of claim 33, wherein:
the lower layer includes titanium (Ti) and the upper layer includes copper (Cu).
